(19) United States
(12) Patent Application Publication
(10) Pub. No.: US 2022/0084618 A1
(43) Pub. Date: Mar. 17, 2022

(54) SYSTEMS AND METHODS FOR USING COLUMN REDUNDANCY FOR ERROR BIT DETECTION AND CORRECTION

(71) Applicant: Micron Technology, Inc., Boise, ID (US)

(72) Inventor: Daniele Vimercati, El Dorado Hills, CA (US)

(21) Appl. No.: 17/023,958

(22) Filed: Sep. 17, 2020

(51) Int. Cl. G11C 29/42; G11C 29/24; G11C 29/00; G11C 29/44

(52) U.S. Cl. CPC G11C 29/42; G11C 29/44; G11C 29/785; G11C 29/24

(57) ABSTRACT

Memory devices may include circuitry to prevent erratic behavior of defective memory cells by detecting and storing a location of defective memory cells in designated Column Redundancy (CR) arrays. Memory devices may also use an Error Correction Code (ECC) scheme to store ECC information for detection and correction of a number of erroneous data bits stored on the memory cells. The ECC information may provide information related to integrity of the data bits of the data array with no regard to possible erratic behavior of memory cells. However, corruption of a data bit is likely to be caused by an erratic behavior of defective memory cells. As such, systems and method for storing a location of one or more erroneous data bits of a dataset obtained using ECC information for reuse. In some embodiments, the memory may store and access such location information using the designated memory cells of one or more CR arrays to correct at least an extra erroneous data bit in a later memory operation.

### BACKGROUND

This section is intended to introduce the reader to various aspects of art that may be related to various aspects of the present techniques, which are described and/or claimed below. This discussion is believed to be helpful in providing the reader with background information to facilitate a better understanding of the various aspects of the present disclosure. Accordingly, it should be understood that these statements are to be read in this light and not as admissions of prior art.

The following relates generally to memory devices and more specifically to improved methods for error detection and correction in memory devices. Generally, a computing system includes processing circuitry, such as one or more processors or other suitable components, and memory devices, such as chips or integrated circuits. One or more memory devices may be used on a memory module, such as a dual in-line memory module (DIMM), to store data and data sets accessible to the processing circuitry. For example, based on a user input to the computing system, the processing circuitry may request that a memory module retrieve data corresponding to the user input from memory cells of different data sets. In some instances, the retrieved data may include firmware, or instructions executable by the processing circuitry to perform an operation and/or may include data to be used as an input for the operation. In addition, in some cases, data output from the operation may be stored in memory cells of different data sets, such as to enable subsequent retrieval of the data from the memory.

Various types of memory devices exist, including random access memory (RAM), read only memory (ROM), dynamic RAM (DRAM), synchronous dynamic RAM (SDRAM), ferroelectric RAM (FeRAM), magnetic RAM (MRAM), resistive RAM (RRAM), flash memory, and others. Memory devices may be volatile or non-volatile. Non-volatile memory, e.g., flash memory, can store data for extended periods of time even in the absence of an external power source. Volatile memory devices, e.g., DRAM, may lose their stored state over time unless they are periodically refreshed by an external power source. A binary memory device may, for example, include a charged or discharged capacitor. A charged capacitor may, however, become discharged over time through leakage currents, resulting in the loss of the stored information. Certain features of volatile memory may offer performance advantages, such as faster read or write speeds, while features of non-volatile memory, such as the ability to store data without periodic refreshing, may be advantageous. Some of the memory devices include memory cells that may be accessed by turning on a transistor that couples the memory cell (e.g., the capacitor) with a word line or a bit line.

Some memory cells in a memory device may exhibit erratic behavior, relating to bad memory cells. For example, some memory cells may experience reliability issues such as low margin or other defects which may affect memory operations. Some memory devices may include circuitry that utilizes code (e.g., Error Correction Code (ECC)) for bit error detection and correction. The circuitry may detect a limited number of bit errors and correct a limited number of bit errors within a segment of memory cells, depending on the ECC that is employed. Moreover, one or more designated redundant memory cells may be provided to allow for the remapping of defective memory cells, based on the detection of errors in a memory segment. However, the redundant memory cells of the memory segment may remain partially unused. That is, some of the redundant memory cells may not be employed and thus represent an underutilized resource and waste of space on the memory device. An approach for an improved error detection and correction method using unused portions of the redundant arrays may be desired.

### BRIEF DESCRIPTION OF THE DRAWINGS

Various aspects of this disclosure may be better understood upon reading the following detailed description and upon reference to the drawings in which:

FIG. 1 is a block diagram of a portion of a memory device, in accordance with an embodiment;

FIG. 2 is a circuit diagram of a memory cell of the memory of FIG. 1, in accordance with an embodiment;

FIG. 3 is a block diagram for fetching a page from a memory array using enhanced Error Correction Code (ECC), in accordance with an embodiment;

FIG. 4A illustrates a column redundancy (CR) array associated with a data set of a data segment that may be used with respect to specific embodiments of the enhanced ECC, in accordance with an embodiment;

FIG. 4B illustrates two CR arrays associated with two respective datasets of a data segment that may be used with respect to specific embodiments of the enhanced ECC, in accordance with an embodiment; and

FIG. 5 illustrates four CR arrays associated with four respective datasets of a data segment that may be used with respect to specific embodiments of the enhanced ECC, in accordance with an embodiment.

### DETAILED DESCRIPTION

When introducing elements of various embodiments of the present disclosure, the articles “a,” “an,” “the,” and “said” are intended to mean that there are one or more of the elements. The terms “comprising,” “including,” and “having” are intended to be inclusive and mean that there may be additional elements other than the listed elements. One or more specific embodiments of the present embodiments described herein will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Different systems and apparatus may include one or memory devices. Memory devices generally include an array of memory cells with each memory cell coupled to at least two access lines. For example, a memory cell may be coupled to a bit line and a word line. A large number of memory cells may be coupled to each access line. Each of the memory cells may have slightly different characteristics, and some memory cells may exhibit defects that may render them unreliable and/or unusable. For example, some memory cells may have a low margin, may be damaged, or may otherwise be likely to fail. Such memory cells may experience erratic behavior and may be considered defective. The erratic behavior of defective memory cells may reduce reliability of data bits stored in the memory cells. Accordingly, memory devices may include circuitry to reduce or prevent such reliability issues by detecting defective memory cells and taking steps to avoid using defective memory cells.

For instance, to mitigate the impact of such defects, memory devices may include designated redundant memory cells, such as Column Redundancy (CR) arrays in addition to the main memory array(s) (also referred to herein as data array(s)). The CR array may include a number of designated memory cells (e.g., CR cells) that may be utilized to replace defective memory cells by remapping defective cell addresses when addressing a detected defective memory cell. Memory devices may use the CR array to store and retrieve data bits that are likely to fail if the detected defective memory cell is utilized. Such memory devices may use fuse circuitry and multiplexers for remapping data bits associated with the detected defective memory cells to the respective CR array.

Because a memory device may include a number of designated redundant memory cells in each CR array to accommodate acceptable volume yields and industry design standards, the number of redundant memory cells provided in the CR array will typically be greater than an acceptable minimum. That is, to ensure acceptable volume yields, only a portion of the designated redundant memory cells will typically be utilized, and thus, many of the redundant memory cells will be unused. For instance, in accordance with manufacturing statistics, less than 30% capacity of each CR array of a typical memory device are utilized in 99.9% of manufactured devices to store CR bits. Accordingly, 70% of each of the CR arrays provided on a typical memory device may be unused, which is an inefficient use of memory space and resources. In accordance with the embodiments provided herein, unused portions of the CR array may be utilized to store information that may be useful in error correction.

As appreciated, memory devices typically use an Error Correction Code (ECC) scheme to detect and correct data errors in the memory array. In general, ECC information (e.g., bits) may be stored with segments of the corresponding data (e.g., datasets) in the memory array. ECC information may be indicative of a number of detected erroneous bits and/or location of erroneous data bits in a data segment stored in the memory array. As such, memory devices may use ECC information to detect and/or correct one or more erroneous data bits of a respective dataset. Different memory devices may use different ECC schemes. For example, a memory device may use an ECC2+1 scheme that detects three bits of erroneous data or corrects up to two bits of erroneous data in a dataset, as will be appreciated.

However, based on limitations of a particular ECC scheme, not all bit errors may be detectable or correctable utilizing the ECC alone. In accordance with embodiments described herein, extra information may be gathered, stored, and used to enhance error correction in the memory device. As described in detail below, memory devices may benefit from storing a location of one or more erroneous data bits of a respective data segment for reuse in later memory operations. In specific examples, the memory device may access and use such previously obtained location information to correct an extra erroneous data bit when ECC information is indicative of three erroneous data bits in a first memory operation cycle, but only can provide location of two erroneous data bits for data error correction (e.g., when an ECC2+1 scheme is employed). In such examples, the memory device may use the previously obtained location of the erroneous data bit in subsequent memory operation cycles to correct one of the erroneous data bits. As such, the memory may correct the two remaining erroneous data bits in the subsequent memory operation cycles using the ECC information.

Moreover, as appreciated, the memory array may store a string of data in partial segments. In some embodiments, a segment may include a number of data bits (e.g., a dataset), a number of corresponding ECC bits, and a number of reserved CR bits. As described above, because most of a CR array is unused, the memory device may store memory cell location information associated with a previously corrected data bit (or a previously detected failed data bit) in the unused portion of the CR arrays. In some embodiments, the memory cell location information associated with the previously corrected data bit may be obtained using the respective ECC information. Such stored memory cell location information may be used for correcting an additional erroneous data bit in a subsequent memory operation cycle. Using this method, memory devices may be provided with extra information to correct one or more extra erroneous data bits in a memory array without using additional memory cells for storage of a data segment.

FIG. 1 illustrates an example of a memory device 100. The memory device 100 may include one or more memory arrays 102. The memory device 100 may be any suitable form of memory, such as non-volatile memory (e.g., FeRam, cross-point memory) and/or volatile memory (e.g., DRAM). The memory device 100 includes memory cells 105 that are programmable to store different states. Each memory cell 105 may be programmable to store two states, denoted as a state 0 and a state 1, for instance. A memory cell 105 may include a capacitor to store a charge representative of the programmable states. For example, a charged and uncharged capacitor may represent two logic states, respectively. DRAM architectures may commonly use such a design, and the capacitor employed may include a dielectric material with linear electric polarization properties.

By contrast, in some embodiments, the memory cell 105 may be configured to store more than two logic states (e.g., three or more values). For example, a ferroelectric memory cell may include a capacitor that has a ferroelectric as the dielectric material. Different levels of charge of a ferroelectric capacitor may represent different logic states. In some embodiments, a ferroelectric capacitor may store a first charge (or first portion of a charge) associated with a dielectric and a second charge (or second portion of a charge) associated with a polarization.

Operations such as reading and writing may be performed on memory cells 105 by activating or selecting the appropriate access lines, such as word line 110 and digit line 115. As will be appreciated, digit lines 115 may also be referred to as bit lines 115. Activating or selecting a word line 110 or a digit line 115 may include applying a voltage to the respective line. Word lines 110 and digit lines 115 are made of conductive materials. For example, word lines 110 and digit lines 115 may be made of metals (such as copper, aluminum, gold, tungsten, etc.), metal alloys, other conductive materials, or the like. According to the example of FIG. 1, each row of memory cells 105 is connected to a single word line 110, and each column of memory cells 105 is connected to a single digit line 115.

By activating one word line 110 and one digit line 115 (e.g., applying a voltage to the word line 110 or digit line 115), a single memory cell 105 of the memory array 102 may be accessed at their intersection. Accessing the memory cell 105 may include reading or writing the memory cell 105. The intersection of a word line 110 and digit line 115 may be referred to as an address of a memory cell 105. In some examples, a read operation may include sensing a voltage or charge level of the memory cell 105. These operations may include sensing a dielectric charge from a memory cell 105 by causing the dielectric charge to be received in a sense component 125, such as a sense amplifier (or “sense amp”), isolating and activating the sense amp, and storing the dielectric charge in a latch. In specific embodiments, these operations may also include sensing a polarization charge from a memory cell by causing the polarization charge to be received in a sense amp, and activating the sense amp. In some examples, based at least in part on the polarity of the dielectric charge and the polarization charge from the memory cell 105, the read operation may include sensing multiple levels.

In some architectures, the logic-storing device of a cell, e.g., a capacitor, may be electrically isolated from the digit line 115 by a selection component. The word line 110 may be connected to and may control the selection component. For example, the selection component may be a transistor and the word line 110 may be connected to the gate of the transistor. Activating the word line 110 results in an electrical connection or closed circuit between the capacitor of a memory cell 105 and its corresponding digit line 115. The digit line may then be accessed to either read or write the memory cell 105. In some examples, the word line 110 may be activated multiple times to facilitate sensing. In some embodiments, the word line 110 may be activated a first time to facilitate sensing of a first charge of a first type (e.g., dielectric charge) and a second time to facilitate sensing of a second charge of a second type (e.g., polarization charge). In some embodiments, the first time and the second time may be discontinuous or separated in time.

Accessing memory cells 105 may be controlled through a row decoder 120 and a column decoder 130. In some examples, a row decoder 120 receives a row address from the memory controller 140 and activates the appropriate word line 110 based on the received row address. Similarly, a column decoder 130 receives a column address from the memory controller 140 and activates the appropriate digit line 115. For example, the memory device 100 may include multiple word lines 110, labeled WL_1 through WL_M, and multiple digit lines 115, labeled DL_1 through DL_N, where M and N depend on the array size. Thus, by activating a word line 110 and a digit line 115, e.g., WL_2 and DL_3, the memory cell 105 at their intersection may be accessed.

Upon accessing, a memory cell 105 may be read, or sensed, by the sense component 125 to determine the stored state of the memory cell 105. For example, after accessing the memory cell 105, the capacitor of the memory cell 105 may discharge a first charge (e.g., a dielectric charge) onto its corresponding digit line 115. In specific embodiments, after accessing the memory cell 105, the capacitor of memory cell 105 may discharge a second charge (e.g., a polarization charge) onto its corresponding digit line 115. Discharging the capacitor may be based on biasing, or applying a voltage, to the capacitor. The discharging may induce a change in the voltage of the digit line 115, which the sense component 125 may compare to a reference voltage (not shown) in order to determine the stored state of the memory cell 105. For example, if the digit line 115 has a higher voltage than the reference voltage, then the sense component 125 may determine that the stored state in memory cell 105 is related to a first predefined logic value. In some embodiments, this first value may include a state 1, or may be another value-including other logic values associated with multi-level sensing that enables storing more than two values (e.g., 3 states per cell or 1.5 bits per cell). The sense component 125 may include various transistors or amplifiers in order to detect and amplify a difference in the signals, which may be referred to as latching. The detected logic state of the memory cell 105 may then be output through the column decoder 130 as an output 135.

A memory cell 105 may be set, or written, by activating the relevant word line 110 and digit line 115. As discussed above, activating a word line 110 electrically connects the corresponding row of memory cells 105 to their respective digit lines 115. By controlling the relevant digit line 115 while the word line 110 is activated, a memory cell 105 may be written—i.e., a state may be stored in the memory cell 105. The column decoder 130 may accept data, for example input 135, to be written to the memory cells 105. In some examples, the memory cell 105 may be written to include multiple charges after a read operation (e.g., based on a write-back operation). In some embodiments, the memory cell 105 may be written after a read operation to writing back data that has been read from the cell (or, alternatively, from other cells in some embodiments) or to refresh data. In some embodiments, a write operation may include writing a first charge (e.g., a polarization charge) and a second charge (e.g., a dielectric charge to memory cell 105). In some embodiments, writing one charge to the memory cell 105 may be based on a voltage of a cell plate relative to a voltage of one or more other components (e.g., a sense amplifier). In some embodiments, writing a first charge (e.g., a polarization charge) to a memory cell 105 may occur before, during an overlapping interval, or at the same time as writing a second charge (e.g., a dielectric charge) to the memory cell 105. In some embodiments, a write operation may be based on setting a polarization state, a dielectric state, or both of the memory cell 105, or by flipping one or more digits using cell or component selection.

In some memory architectures, accessing the memory cell 105 may degrade or destroy the stored logic state and re-write or refresh operations may be performed to return the original logic state to the memory cell 105. In DRAM, for example, the capacitor may be partially or completely discharged during a sense operation, corrupting the stored logic state. Therefore, the logic state may be re-written after a sense operation. Additionally, activating a single word line 110 may result in the discharge of all memory cells in the row, thus, several or all memory cells 105 in the row may need to be re-written, as will be appreciated.

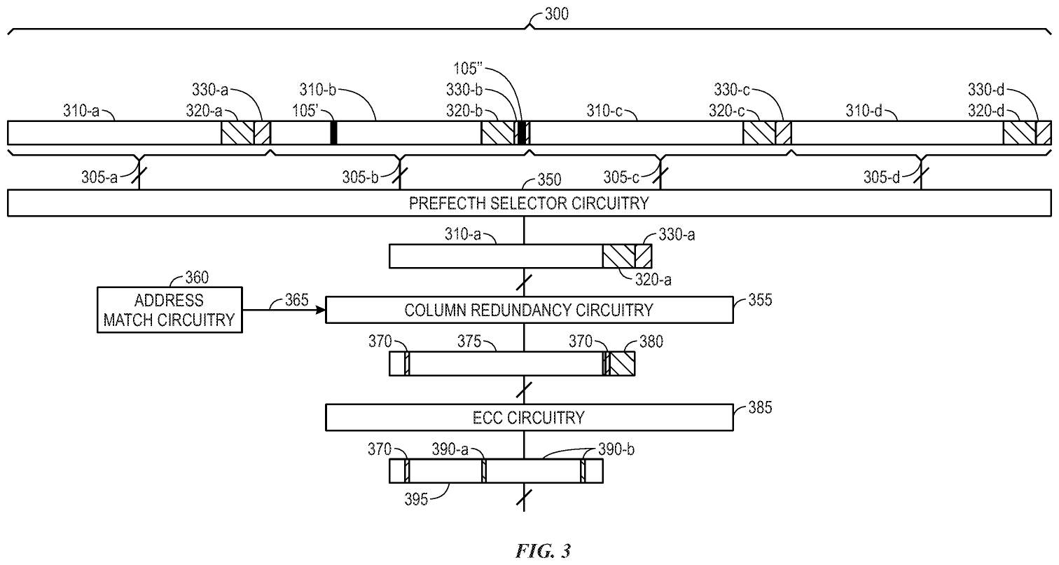

In some embodiments, a memory device 100 may store strings of bits using a number of memory cells 105. For example, a number of designated memory cells 105 may be used to store a first dataset. Multiple datasets may form a data string which may be stored in the memory array 102 as a page. For instance, data may be stored and accessed as a 1024-bit page including 256 bits of data in each of four datasets. In some embodiments, each dataset may include strings of data in partial segments stored on memory cells 105, as well as additional bits, as will be described in greater detail below with regard to FIG. 3. For example, each segment may include a dataset of a number of data bits for storage/retrieval in the memory array 102, ECC bits used for detecting and correcting errors in the data bits, and CR bits for use in replacing bad memory cells 105. As will be described in greater detail below, in accordance with the disclosed embodiments, unused portions of the CR array may be employed to store useful information, such as the position of a previously detected defective cell. This information may provide enhanced correction capabilities, compared to using ECC, alone.

The memory controller 140 may control the operation (e.g., read, write, re-write, refresh, etc.) of the memory cells 105 through the various components, such as the row decoder 120, the column decoder 130, and the sense component 125. The memory controller 140 may generate row and column address signals in order to activate the desired word line 110 and digit line 115. The memory controller 140 may also provide and control various voltage levels used during the operation of memory device 100. For example, the memory controller 140 may provide instructions for storing a data string on a number of memory cells 105. In general, the amplitude, shape, or duration of an applied voltage may be adjusted or varied and may be different for the various operations for operating memory device 100. Furthermore, one, multiple, or all memory cells 105 within memory device 100 may be accessed simultaneously. For example, multiple or all cells of memory device 100 may be accessed simultaneously during a reset operation in which all memory cells 105, or a group of memory cells 105, are set to a single logic state. In some embodiments, the memory controller 140 may include an ECC engine. For example, the memory controller 140 may use the ECC engine to generate ECC information associated with each respective dataset or group of datasets (e.g., data string). The memory device 100 may then write the generated ECC information with corresponding segments of the respective datasets. Moreover, the memory controller 140 may use ECC information of datasets to detect and correct a number of data errors associated with the respective data arrays.

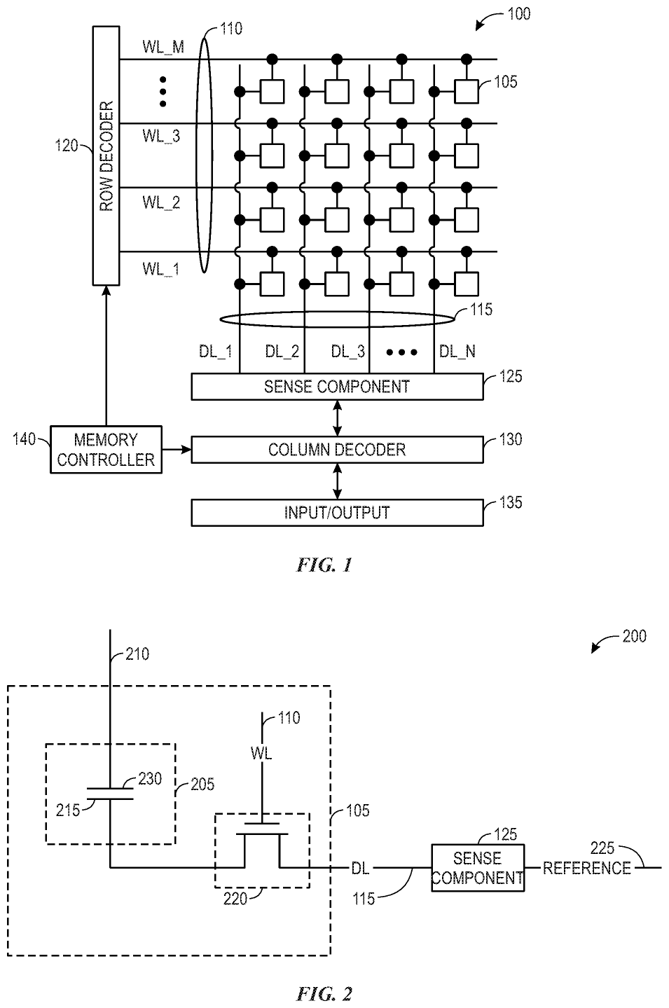

FIG. 2 illustrates an example circuit 200 that includes a memory cell 105. The circuit 200 may store a state of a bit (e.g., data bit) For example, the memory controller 140 of FIG. 1 may provide instructions for storing a data bit of a respective data array on a memory cell 105 of the circuit 200. The circuit 200 includes the memory cell 105, word line 110, digit line 115, and sense component 115, which may be examples of a memory cell 105, word line 110, digit line 115, and sense component 125, respectively, as described with reference to FIG. 1. The memory cell 105 may include a logic storage component, such as a capacitor 205 that has a first plate, cell plate 230, and a second plate, cell bottom 215. The cell plate 230 and the cell bottom 215 may be capacitively coupled. The orientation of the cell plate 230 and the cell bottom 215 may be flipped without changing the operation of memory cell 105. The circuit 200 also includes selection component 220 and reference signal 225. In the example of FIG. 2, the cell plate 230 may be accessed via a plate line 210 and the cell bottom 215 may be accessed via the digit line 115. As described above, various states may be stored by charging or discharging the capacitor 205.

The stored state of the capacitor 205 may be read or sensed by operating various elements represented in the circuit 200. The capacitor 205 may be in electronic communication with the digit line 115. For example, the capacitor 205 can be isolated from the digit line 115 when the selection component 220 is deactivated, and the capacitor 205 can be connected to the digit line 115 when the selection component 220 is activated. Activating the selection component 220 may be referred to as selecting memory cell 105.

In some embodiments, the selection component 220 is a transistor and its operation is controlled by applying a voltage to the transistor gate, where the voltage magnitude is greater than the threshold magnitude of the transistor. The word line 110 may activate the selection component 220. For example, a voltage applied to the word line 110 is applied to the transistor gate, connecting the capacitor 205 with the digit line 115. In an alternative embodiment, the positions of the selection component 220 and the capacitor 205 may be switched. That is, the selection component 220 may be connected between the plate line 210 and the cell plate 230 and the capacitor 205 may be positioned between the digit line 115 and the other terminal of the selection component 220. In this embodiment, the selection component 220 may remain in electronic communication with the digit line 115 through the capacitor 205.

The biasing plate line 210 may result in a voltage difference (e.g., plate line 210 voltage minus digit line 115 voltage) across the capacitor 205. The voltage difference may yield a change in the stored charge on the capacitor 205, where the magnitude of the change in stored charge may depend on the initial state of the capacitor 205 (e.g., state 1, state 0, one of three or more possible values). This may induce a change in the voltage of the digit line 115 based on the charge stored on the capacitor 205.

The induced change in voltage of the digit line 115 may depend on a capacity of the capacitor 205. The digit line 115 may connect other memory cells 105 as depicted in FIG. 1. The resulting voltage of the digit line 115 may then be compared to a reference (e.g., a voltage of reference line 225) by the sense component 115 in order to determine the stored logic state in memory cell 105. In different embodiments, other sensing processes may be used. The sense component 115 may latch the induced voltage change on the digit line 115 to determine the stored state in memory cell 105 (e.g., state 0, 1, a second or a third of three possible values) The latched voltage of the memory cell 105 may then be output, for example, through the column decoder 130 as an output 135 with reference to FIG. 1.

To write to the memory cell 105, a voltage may be applied across the capacitor 205. For example, the selection component 220 may be activated through the word line 110 in order to electrically connect the capacitor 205 to the digit line 115. A voltage may be applied across the capacitor 205 by controlling the voltage of the cell plate 230 (through the plate line 210) and the cell bottom 215 (through the digit line 115). For example, the voltage magnitude of the cell plate 230 may be a value between the supply voltages of the sense component 115 and ground (e.g., 0) To write a state 0 (or a first predefined logic value of three or more possible values), the cell plate 230 may be taken high, that is, a positive voltage may be applied to the plate line 210, and the cell bottom 215 may be taken low, e.g., virtually grounding or applying a negative voltage to the digit line 115. The opposite process is performed to write a state 1 (or a first predefined logic value of three or more possible values), where the cell plate 230 is taken low and the cell bottom 215 is taken high. That said, in different embodiments, the circuit 200 may perform memory operations (e.g., read, write, etc.) using different circuit elements or by performing different memory operations than what is described above.

Some memory cells 105 may become unreliable or develop a high probability of failure compared to other memory cells 105. Such memory cells 105 may become defective. For example, a defective memory cell 105 may have failed a sensing operation previously, the memory cell 105 may have been identified as “stuck” (e.g., held to a 1 or 0), or the memory cell 105 may have a certain high probability of failure for other reasons. In accordance with the present embodiments, the memory device 100 may benefit from storing useful and accessible information in unused portions of the memory device 100 to identify and correct one or more defective memory cells 105 for use during subsequent memory operations. In some embodiments, a defective memory cell 105 may be correctable using an ECC scheme. However, the ECC scheme may be limited to correction of a specific number of errors (e.g., ECC2+1). Accordingly, it may be useful to store the address of one or more detected defective memory cells 105, identified during a first ECC operation, for later use (e.g., during a second ECC operation after the first ECC cycle). In some examples, the memory device 100 may use the unused portion of one or more CR arrays to store the address of defective memory cells 105.

Referring now to FIG. 3, a block diagram for fetching a page 300 from the memory device 100 is illustrated. The page 300 may be previously stored in respective memory cells 105 of the memory array 102, as will be appreciated. In the illustrated example, the page 300 may be a 1024-bit page of data bits (e.g., 4 segments, each including 256 data bits). The page 300 may include a segment 305-a, a segment 305-b, a segment 305-c, and a segment 305-d. The segment 305-a, the segment 305-b, the segment 305-c, and the segment 305-d may be stored on adjacent memory cells 105 or stored on memory cells 105 with different positions on the memory device 100. Nevertheless, the memory device 100 may access memory cells 105 associated with the segment 305-a, the segment 305-b, the segment 305-c, and the segment 305-d consecutively during a prefetch operation. It should be appreciated that in different examples, a different number of segments 305 may be accessed during a prefetch and each segment 305 may include a different number of bits.

For example, the segment 305-a may include a dataset 310-a including a number of data bits (e.g., 256 data bits) and additional information for enhancing reliability of the data bits. The data bits associated with the dataset 310-a may include a first portion of information stored along with the dataset 310-a as part of the segment 305-a. The additional information may include ECC bits 320-a (e.g., 20 ECC bits) and CR bits 330-a (e.g., 12 CR bits). The ECC bits 320-a may be indicative of respective ECC information. The CR bits 330-a may include information relating to the remapping of data bits associated with the defective memory cells 105 in memory array 102 to be replaced with designated redundant memory cells 105 in the CR array.

The segment 305-b, the segment 305-c, and the segment 305-d may include similar data structures. That is, the segment 305-b may include a dataset 310-b including a number of data bits (e.g., 256 data bits). The data bits of the dataset 310-b may include a second portion of information stored along with the dataset 310-b as part of the segment 305-b. The additional information may include ECC bits 320-b (e.g., 20 ECC bits) and CR bits 330-b (e.g., 12 CR bits). The ECC bits 320-b may be indicative of respective ECC information. The CR bits 330-b may include information relating to the remapping of data bits associated with the defective memory cells 105 in memory array 102 to be replaced with designated redundant memory cells 105 in the CR array.

Similarly, the segment 305-c may include a dataset 310-c including a number of data bits (e.g., 256 data bits). The data bits of the dataset 310-c may include a third portion of information stored along with the dataset 310-c as part of the segment 305-c. The additional information may include ECC bits 320-c and CR bits 330-c. The ECC bits 320-c may be indicative of respective ECC information. The CR bits 330-c may include information relating to the remapping of data bits associated with the defective memory cells 105 in memory array 102 to be replaced with designated redundant memory cells 105 in the CR array.

Moreover, the segment 305-d may include a dataset 310-d including a number of data bits (e.g., 256 data bits). The data bits of the dataset 310-d may include a fourth portion of information stored along with the dataset 310-d as part of the segment 305-d. The additional information may include ECC bits 320-d and CR bits 330-d. The ECC bits 320-d may be indicative of respective ECC information. The CR bits 330-d may include information relating to the remapping of data bits associated with the defective memory cells 105 in memory array 102 to be replaced with designated redundant memory cells 105 in the CR array.

In some embodiments, the memory device 100 may store the ECC bits 320 with the respective datasets 310. The ECC bits 320 may be indicative of ECC information associated with the respective datasets 310. Each of the segments 305 may include a CR array including a number of designated memory cells 105 for storing respective CR bits 330 associated with the respective dataset 310.

In specific embodiments, as described with respect to FIGS. 3-5, each segment 305 may include twenty ECC bits 320. It should be appreciated that the number of ECC bits 320 may vary in different embodiments and the specific embodiments discussed herein are only by the way of example.

An ECC engine (not shown) may generate the ECC bits 320 and use the ECC bits 320 to detect and correct certain errors in the associated dataset 310. The ECC engine may be implemented using hardware, software, firmware, etc. In some embodiments, the memory device 100 may include the ECC engine, whereas in other embodiments, the ECC engine may be external to the memory device 100. In specific embodiments, the memory controller 140 may include the ECC engine to generate the ECC bits 320 associated with dataset 310. In such embodiments, the memory controller 140 may use the ECC engine to generate the respective ECC bits 320 upon receiving and/or transmitting the dataset 310. Alternatively, the memory device 100 may receive the dataset 310 with the respective ECC bits 320.

The ECC bits 320 may be used to detect and correct a number of erroneous data bits associated with a respective dataset 310. The ECC bits 320 may also include information for obtaining a location of certain number of data errors of data bits associated with the respective dataset 310 and thereby facilitate correcting the data errors. For example, the ECC engine may generate ECC bits 320 using ECC2+1 scheme that may detect up to three data errors, or provides information for detecting and correcting two data errors in the dataset 310. An ECC scheme may provide ECC information for detecting and/or correcting a number of erroneous data bits in a respective dataset 310 with no regard to potential cause of the errors or recurring data errors on specific memory cells 105.

On the contrary, the CR bits 330 may include information relating to remapping of data bits associated with the defective memory cells 105 to be replaced with designated redundant memory cells 105 in a respective CR array. For example, the CR bits 330-a may include information relating to the remapping of data bits addressed to the defective memory cells 105 associated with the dataset 310-a to the CR bits 330-a. The CR bits 330-b, CR bits 330-c, and CR bits 330-d may include similar information with respect to dataset 310-b, dataset 310-c, and dataset 310-d.

In specific embodiments, as described with respect to FIGS. 3-5, a respective CR array of a segment 305 may include twelve designated memory cells 105 for storing the respective CR bits 330. The memory device 100 may use address match circuitry 360 in relation to the CR bits 330. The address match circuitry 360 may include information identifying one or more defective memory cells 105 on the memory device 100. Using the address match circuitry 360, the memory device 100 may utilize one or more designated memory cells 105 of a respective CR array to replace defective memory cells 105. That is, the address match circuitry 360 may remap data bits addressed to the previously identified defective memory cell 105 to the designated memory cells 105 of the respective CR array as the CR bits 335 (i.e., remapped data bits).

For example, a memory write operation may include instructions for writing a first data bit of the dataset 310-b on a first memory cell 105′. The memory device 100 may compare an address of the first memory cell 105′ with one or more previously stored defective memory cell addresses using the address match circuitry 360. Upon determination of a match between the address of the first memory cell 105′ and a previously stored defective memory cell address, the memory device 100 may remap the first data bit to a second memory cell 105″ designated to the CR array 330-b. Accordingly, the memory device 100 may remap the first data bit for storage using the second memory cell 105″. Similar circuitry may be used for accessing CR bits 330-b (and/or other CR bits 330) using the address match circuitry 360. The read operations for accessing CR bits 330 may be described below with respect to embodiments of FIGS. 3-5.

In some examples, a respective segment 305 may include a number of unused CR bits 330. For example, the dataset 310-a may be stored on a number of memory cells 105 and include only two defective memory cells 105 to be remapped to the CR array. The memory device 100 may remap the data bits associated with the two defective memory cells 105 to the CR bits 330-a. The two CR bits 330-a associated with the remapped memory cells 105 may be stored using two of the twelve designated memory cells 105 of the respective data array. As such, the CR bits 330-a may include an unused portion including ten unused CR bits 330-a, since a designated number of CR bits of the segment 305 are reserved for inclusion of bits for remapping to the CR array. Different segments 305 may include different numbers of unused CR bits 330.

During a memory operation, the memory device 100 may access all memory cells 105 associated with a segment 305. For example, the memory device 100 may access the dataset 310 and the CR bits 330, including the unused CR bits 330. According to specific embodiments described herein, the unused CR bits 330 may be populated with useful and accessible information. For example, the unused CR bits 330 may be populated to include information that may be helpful to improve error correction without using additional resources.

In a specific example, the ECC bits 320-b may be used to identify a first erroneous data bit associated with the first memory cell 105′ during a first ECC operation cycle. As will be appreciated, if the data error detected by the ECC code is the only error, most ECC algorithms will be able to detect and correct the single error. However, if additional cells of the data bits 310-b subsequently fail, the number of failures may exceed capabilities of the ECC being implemented. However, because a faulty memory cell 105′ is likely to fail again in the future, information regarding the failure may be stored and used to enhance the ECC capabilities, since the first memory cell 105′ is likely to be the cause of a subsequent data error, as well. For example, the memory device 100 may store extra information indicative of the address of the first memory cell 105′ on unused CR bits 330-b. The extra information stored on unused CR bits 330 are referred to hereinafter as CR extra bits. As described in detail below, the CR extra bits may be used to enhance the ECC capabilities of the memory device 100.

The memory device 100 may use the CR extra bits for identifying the specific position of the erroneous first memory cell 105′ during a later memory operation. In different embodiments, the ECC engine, the memory controller 140, or other circuitry of the memory device 100 may use the CR extra bits to enhance the error correction (e.g., enhanced the ECC capabilities) in subsequent ECC operations. The enhanced error correction may provide additional error detection and correction ability to improve reliability of the memory device 100. The memory device 100 may use respective ECC bits 320 (e.g., ECC bits 320-b) and the information in respective CR extra bits (e.g., CR extra bits associated with the respective CR array of CR bits 330-b) to obtain the enhanced error correction.

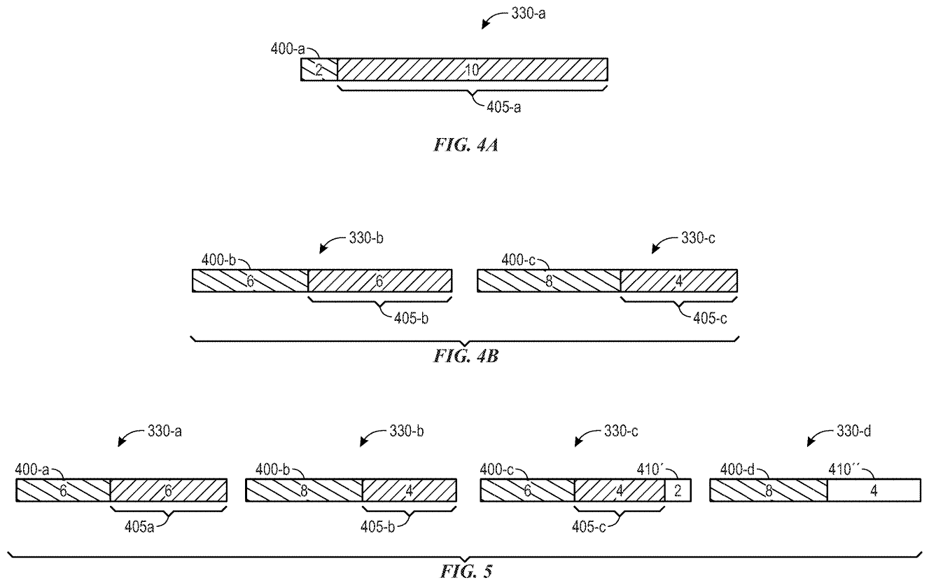

In different embodiments, the CR bits 330-a, the CR bits 330-b, the CR bits 330-c, and the CR bits 330-d, may each include a different number of unused CR bits 330 (i.e., CR extra bits). As such, the respective CR extra bits of the CR bits 330 may each include respective address information identifying a defective memory cell 105. In some embodiments, the CR extra bits may be used to store only a portion of the address information identifying a defective memory cell 105. For example, the CR extra bits associated with CR bits 330-a may include address information indicative of location of a first defective memory cell 105, whereas, the CR extra bits associated with CR bits 330-b and the CR extra bits associated with CR bits 330-c may each include a portion of address information indicative of location of a different defective memory cell 105. The second defective memory cell 105 may be associated with the dataset 310-b, dataset 310-c, or another dataset 310. Further, in another embodiment, there may be enough CR extra bits to store address information for 2 or more bit errors in the dataset 310. A specific embodiment of the CR bits 330-a, the CR bits 330-b, the CR bits 330-c, the CR bits 330-d, and the respective CR extra bits will be depicted and described in greater detail below, with respect to FIGS. 4A, 4B, and 5.

Generally, error detection and correction in a data read process from the page 300 may be described below. The data read process may be with respect to specific embodiments of the memory device 100 and FIGS. 3-5. The memory device 100 may include prefetch selector circuitry 350. In the specific embodiment of FIG. 3, the memory device 100 may use the prefetch selector circuitry 350 to fetch the segment 305-a, the segment 305-b, the segment 305-c, and the segment 305-d of the page 300. In one embodiment, each segment 305 comprises 256 data bits. The prefetch selector circuitry 350 may access memory cells 105 associated with the segment 305-a, the segment 305-b, the segment 305-c, and the segment 305-d. For example, the prefetch selector circuitry 350 may first provide the data bits associated with the segment 305-a to a CR circuitry 355 for facilitating memory read operations.

The CR circuitry 355 may operate in parallel with the address match circuitry 360 to generate and provide a CR corrected dataset 375, using the CR bits 330-a, associated with the segment 305-a, for instance. The address match circuitry 360 may include one or more addresses of defective memory cells 105 previously stored thereon, based on the information accessed in the CR bits 330-a. The previously stored defective memory cell addresses may be indicative of defective memory cells 105 in the memory device 100. The address match circuitry 360 may use fuse circuitry and/or logic circuitry to store defective memory cell addresses and/or perform address match operations.

The CR circuitry 355 may use the address match circuitry 360 to compare memory cell addresses of data bits associated with the dataset 310-a with the previously stored defective memory cell addresses. Upon finding an address match, the CR circuitry 355 may provide one or more column repair bits (e.g., by remapping the CR bits 330) instead of the detected defective memory cell 105. For example, CR corrected data bits 370 may be mapped from the CR bits 330-a to the matched addresses in dataset 310-a and the ECC bits 320-a. As such, the CR circuitry 355 may provide the CR corrected dataset 375 and CR corrected ECC bits 380, including the CR corrected data bits 370, to an ECC circuitry 385. Thus, in the present example, two bits of the CR bits 330-a were used to remap bits of the dataset 310-a to provide corrected data bits 370 in the CR corrected dataset 375 and CR corrected ECC bits 380.

In addition, and in accordance with the present embodiments, the CR circuitry 355 may use the CR extra bits (i.e., the unused portion of the CR bits 330) to provide additional capability in addition to the remapping of the defective memory cells 105. For example, the CR circuitry 355 may correct an additional erroneous data bit of the ECC bits 320-a using information stored in the respective CR extra bits, as will be described below. It should be appreciated that in other embodiments, a respective dataset 310 may include a different number of defective memory cells 105. In such embodiments, a different number of CR bits 330 may be mapped to the respective dataset 310.

The ECC circuitry 385 may receive the CR corrected dataset 375 and the CR corrected ECC bits 380. The ECC circuitry 385 may include circuitry to use the CR corrected ECC bits 380 and correct two erroneous data bits (e.g., first ECC corrected data bit 390-a and second ECC corrected data bit 390-b) detected by the ECC of the ECC circuitry 385 in the CR corrected dataset 375. For example, the ECC circuitry 385 may use an ECC engine to correct two detected erroneous data bits and provide the first ECC corrected data bit 390-a and the second ECC corrected data bit 390-b. The ECC circuitry 385 may provide an output dataset 395 that includes the CR corrected data bit 370 and the two ECC corrected data bits 390. However, during a subsequent cycle, if an additional bit error is detected using ECC2+1 code, the ECC circuitry 385 will not be able to correct the third error, due to limitations in the capabilities of the particular ECC code being implemented.

In accordance with the embodiments described herein, the memory device 100 may use the CR extra bits (i.e., the previously unused portion of the CR bits 330) to store information about a detected error (e.g., a bit position in the dataset 310) to correct an additional erroneous data bit in the output dataset 395 during a subsequent cycle. Moreover, the output dataset 395 may correspond to input/output block 135 in FIG. 1. In some embodiments, the memory controller 140 may facilitate the described operations of FIG. 3. In other embodiments, different circuitry may facilitate the described error correction methods.

In specific embodiments, the memory device 100 may store an address of an erroneous data bit (e.g., a bit from the dataset 310-a that fails an ECC check during a first read cycle), for example the first ECC corrected data bit 390-a, using the respective CR extra bits. As the ECC bits 320-a were used to identify the first ECC corrected data bit 390-a, the memory cell 105 associated with the first ECC corrected data bit 390-a is likely to be the cause of a subsequent error. As such, the memory device 100 may provide enhanced error correction capability by using the CR extra bits to identify the first ECC corrected data bit 390-a in subsequent memory operations without using the ECC bits 320-a. Accordingly, in subsequent memory operations, the ECC bits 320-a may facilitate correction of two erroneous data bits, different from the first ECC corrected data bit 390-a. It should be appreciated that the CR extra bits may or may not be used in subsequent memory operations, although they may be stored on the respective unused memory cells 105 of one or more data segments 305. Moreover, in different embodiments, the respective CR extra bits may be associated with the segment 305-a, or other segments 305, as will be appreciated.

In FIG. 4A, a specific embodiment of the CR bits 330-a, including used CR bits 400-a and CR extra bits 405-a, is depicted. The “used CR bits” 400 generally refer to the portion of the CR bits 330-a, wherein prior errors in the memory array (i.e., bad cells) have been replaced with good cells in the CR array. As previously described, the “CR extra bits” 400 generally refer to the remaining bits of the CR bits 330 that were not used to replace bad cells of the memory array. In the depicted embodiment, the CR bits 330-a may be stored on twelve memory cells 105 designated for storage of the CR information associated with the dataset 310-a. The memory device 100 may store the redundant (used) CR bits 400-a in the respective CR array and store the CR extra bits 405-a in the unused portion of the respective reserved CR bits 330-a. The used CR bits 400-a may include two data bits stored using two memory cells 105 associated with the reserved CR bits 330-a of the respective CR array. The CR extra bits 405-a may be stored on the unused memory cells 105 of the respective CR array. Accordingly, the CR extra bits 405-a may include up to ten data bits. In specific examples, the CR extra bits 405-a may include address information indicative of a specific position of an erroneous data bit among 1024 memory cells 105 using the ten data bits. In other embodiments, the CR extra bits 405-a may include address information indicative of a specific position of an erroneous data bit among a different number of memory cells 105. In the previous example, wherein a dataset 310-a is 256 bits, each bit of the dataset 310-a can be addressed using 8 additional bits (2⁸). Further, to address a 256 bit dataset 310 and 20 ECC bits 320, one additional bit (2⁹) would provide sufficient addressability. Accordingly, in the illustrated example, 9 of the 10 bits of the unused CR extra bits 405-a would be sufficient to store address information of any of the bits in the dataset 310-a or the ECC bits 320-a for later usage.

The memory device 100 may use the CR extra bits 405-a during a memory operation for correcting one or more additional errors in a dataset 310, such as dataset 310-a. For example, the CR extra bits 405-a may be indicative of a defective memory cell 105 used by the dataset 310-a to store information. In some embodiments, the CR extra bits 405-a may include a portion of an address of a likely defective memory cell 105. In some examples, the address of the likely defective memory cell 105 is determined during previous ECC operations. In such embodiments, the CR extra bits 405-a may be sufficient for identifying a location of an erroneous data bit in the dataset 310-a. In other embodiments, the CR extra bits 405-a may include a portion of information that is sufficient for identifying location of an erroneous data bit in a different dataset 310 (e.g., dataset 310-b). Yet in other embodiments, other useful data may be stored on the unused and designated memory cells 105 of the CR array 330-a (i.e., CR extra bits 405-a) as well.

In FIG. 4B, another specific embodiment of the CR bits 330-b, including used CR bits 400-b and CR extra bits 405-b, and the CR bits 330-c, including used CR bits 400-c and CR extra bits 405-c, is depicted. The used CR bits 400-b and the CR extra bits 405-b may be stored on twelve memory cells 105 designated to the CR information for dataset 310-b. Also, the CR bits 330-c, including the used CR bits 400-c and the CR extra bits 405-c may be stored on twelve memory cells 105 designated for storage of the CR information for dataset 310-c. The memory device 100 may store the used CR bits 400-b in the respective CR array, the CR extra bits 405-b in the unused portion of the respective CR bits 330-b, the CR bits 400-c in the respective CR array, and the CR extra bits 405-c in the unused portion of the respective CR bits 330-c.

The used CR bits 400-b may include six data bits stored using six memory cells 105 associated with the respective CR array. The CR extra bits 405-b may be stored on the unused memory cells 105 of the respective CR array, that may be designated for storing the CR information. Accordingly, the CR extra bits 405-b may include six data bits.

Also, the CR bits 400-c may include eight data bits stored using eight memory cells 105 associated with the respective CR array. The CR extra bits 405-c may be stored on the unused memory cells 105 of the respective CR array, that may be designated for storing the CR information. Accordingly, the CR extra bits 405-c may include four data bits.

With the foregoing in mind, the CR extra bits 405-b or the CR extra bits 405-c may not include sufficient information separately to facilitate identification of a position of an erroneous data bit. As such, the CR extra bits 405-b and the CR extra bits 405-c may share information indicative of a location of an erroneous data bit. For example, the CR extra bits 405-b and the CR extra bits 405-c may each include a portion of information indicative of position of an erroneous data bit associated with the dataset 310-b, the dataset 310-c, or other datasets 310. In some examples, the position information stored on the CR extra bits 405-b and the CR extra bits 405-c may be determined using previous ECC operations. Also, the CR extra bits 405-b and the CR extra bits 405-c may be stored during a previous memory operation. The memory device 100 may include appropriate circuitry (e.g., memory controller 140) to obtain the location of the erroneous data bit using the CR extra bits 405-b and the CR extra bits 405-c, which may be used in tandem to provide the address location of an additional erroneous data bit.

Referring now to FIG. 5, a different embodiment of the CR bits 330-a, including used CR bits 400-a and CR extra bits 405-a, the CR bits 330-b, including used CR bits 400-b and CR extra bits 405-b, the CR bits 330-c, including used CR bits 400-c and CR extra bits 405-c, and the CR bits 330-d, including used CR bits 400-d, is depicted. The CR extra bits 405-a, the CR extra bits 405-b, and the CR extra bits 405-c may each include a portion of information indicative of an erroneous data bit. The specific embodiment of FIG. 5 also includes second ECC bits 405 associated with the CR array. In the depicted example, the second ECC bits 405 may include a first portion of second ECC bits 410′ and a second portion of second ECC bits 410″.

The used CR bits 400-a may include six data bits, the used CR bits 400-b may include eight data bits, the used CR bits 400-c may include six data bits, and the used CR bits 400-d may include eight data bits. As such, the CR extra bits 405-a may be stored using the remaining designated memory cells 105 associated with the respective CR array, the CR extra bits 405-b may be stored using the remaining four memory cells 105 associated with the respective CR array, the CR extra bits 405-c may be stored using four of the remaining six memory cells 105 associated with the respective CR array 330. Moreover, the memory device 100 may store the second ECC bits 405 on a number of available memory cells 105 associated with one or a number of respective CR arrays to provide enhanced error correction. For example, the memory device 100 may store the first portion of the second ECC bits 405-a with the used CR bits 400-c and CR extra bits 405-c using the four remaining designated memory cells 105 associated with the respective CR array and store the second portion of the second ECC bits 405-b with the CR bits 330-d on the four remaining memory cells associated with the respective CR array. In other embodiments, other useful information bits may be stored on the unused designated memory cells 105 of different CR arrays for enhanced error correction.

The second ECC bits 405 may include ECC information related to the CR extra bits 405-a, the CR extra bits 405-b, and the CR extra bits 405-c. Accordingly, the second ECC bits 405 may include redundant error detection and correction for CR extra bits 400. The memory device 100 may use the second ECC bits 405 for redundant error detection and correction without using additional resources. For example, a number of erroneous data bits may be detected and/or corrected in the CR extra bits 405-a, the CR extra bits CR extra bits 405-b, and the CR extra bits 405-c using the ECC engine and/or ECC circuitry 385. In different embodiments, the second ECC bits 405 may include ECC information related to other data segments.

Moreover, it should be appreciated that the number of available memory cells 105 associated with different CR arrays, the number of data bits associated with the CR bits 330, including the used CR bits 400 and the CR extra bits 400, the second ECC bits 405, and data bits of the respective datasets 310 are by the way of example, and in other embodiments, other viable number of data bits and memory cells may be used. The circuitry and methods described may be modified to be used with different arrangement of segments 305 and the memory cells 105 associated with segments 305. For example, the page 300, the datasets 310, the ECC bits 320, and/or the CR bits 330 may each include a different number of memory cells and/or data bits while using substantially the same circuitry and methods for implementing the CR extra bits 400, CR corrected ECC 380, and/or the second ECC bits 405.

Furthermore, the circuitry and methods described may provide technical solutions to solve technical problems in memory devices and memory arrays. For example, the described methods and circuitry may provide efficient use of memory cells of a memory device with enhanced data integrity using additional layer of error detection and/or correction. The described methods and circuitry may provide technical enhancements with no significant increase in use of power, time, or other resources.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

1. A memory device comprising:
a memory array comprising a first data segment, wherein the first data segment comprises:
a first dataset portion comprising a first number of dataset memory cells, the first number of dataset memory cells configured to store a first number of data bits; and
a first Column Redundancy (CR) portion comprising a first number of CR memory cells, the first number of CR memory cells configured to store first CR bits and first additional bits, wherein:
storing the first CR bits comprise remapping one or more data bits of the first number of data bits from the dataset memory cells to the CR memory cells; and
the first additional bits comprise at least a first portion of additional information associated with an address of a first memory cell associated with the memory device.

2. The memory device of claim 1, wherein the first memory cell is associated with the first number of dataset memory cells, and is associated with a previously identified erroneous data bit.

3. The memory device of claim 2, wherein the previously identified erroneous data bit is identified using Error Correction Code (ECC) circuitry.

4. The memory device of claim 1, wherein:
the first additional bits are generated during a first ECC cycle; and
the first additional bits are accessed during a second ECC cycle, subsequent to the first ECC cycle.

5. The memory device of claim 1, wherein the memory device is configured to correct an erroneous data bit associated with the first dataset portion by accessing the first additional bits.

6. The memory device of claim 5, wherein:
the memory device is configured to correct a first number of erroneous data bits of the first number of data bits using an ECC stored in association with the first dataset portion; and
the memory device is configured to correct an additional erroneous data bit of the first number of data bits using the first additional bits.

7. The memory device of claim 1, wherein the memory array comprises a second data segment, the second data segment comprising a second CR portion comprising a second number of CR memory cells, the second number of CR memory cells configured to store second additional bits, wherein the second additional bits comprise at least a second portion of the additional information associated with the address of a first memory cell associated with the memory device.

8. The memory device of claim 7, wherein:
the memory device is configured to correct a first number of erroneous data bits of the first number of data bits using an ECC stored in association with the first dataset portion; and
the memory device is configured to correct an additional erroneous data bit of the first number of data bits using the first additional bits and the second additional bits.

9. The memory device of claim 1, wherein the memory device comprises:
a second data segment comprising a second CR portion, the second CR portion is configured to store second additional bits;
a third data segment comprising a third CR portion, the third CR portion is configured to store third additional bits; and
a fourth data segment comprising a fourth CR portion, the fourth CR portion is configured to store fourth additional bits;
wherein the memory device is configured to use the first additional bits, second additional bits, third additional bits, and fourth additional bits to identify position of an erroneous data bit stored on the first dataset portion.

10. The memory device of claim 9, wherein at least a portion of the additional information stored on the first additional bits, the second additional bits, the third additional bits, or the fourth additional bits is associated with a redundant ECC, wherein the memory device is configured to use the redundant ECC to identify at least an erroneous bit.

11. A method comprising:
storing, using a controller, first Column Redundancy (CR) bits on at least one memory cell of a number of memory cells of a first CR array, the first CR array associated with a first dataset;
detecting, using the controller, a number of unused memory cells of the first CR array;
detecting, using the controller, a first address of a memory cell associated with a detected erroneous data bit during a first memory operation cycle;
storing, using the controller, first additional information, the first additional information indicative of at least a first portion of the first address using the detected unused memory cells;
detecting, using the controller, a number of errors associated with the first dataset during a second memory operation cycle, the second memory operation cycle occurring subsequent to the first memory operation cycle; and
correcting, using the controller, at least a first error associated with the first dataset of the number of errors associated with the first dataset using at least a portion of the first additional information.

12. The method of claim 11, wherein the first additional information is indicative of the first address of an erroneous bit.

13. The method of claim 11, comprising:
detecting, using the controller, second additional information, the second additional information indicative of at least a second portion of the first address and stored on unused memory cells of a second CR array associated with a second dataset;
correcting, using the controller, the first error associated with the first dataset of the number of errors associated with the first dataset using at least a portion of the first additional information and at least a portion of the second additional information.

14. The method of claim 11, comprising:
detecting, using the controller, second additional information, the second additional information associated with the first address and stored on unused memory cells of a second CR array associated with a second dataset;
detecting, using the controller, third additional information, the third additional information associated with the first address and stored on unused memory cells of a third CR array associated with a third dataset;
detecting, using the controller, fourth additional information, the fourth additional information associated with the first address and stored on unused memory cells of a fourth CR array associated with a fourth dataset;
determining, using the controller, redundant ECC information associated with correcting additional erroneous data bits stored using the first additional information, the second additional information, the third additional information, the fourth additional information, or a combination thereof, and
correcting, using the controller, an erroneous data bit using the redundant ECC information.

15. An apparatus comprising:
a memory array comprising a first data segment, wherein the first data segment comprises:
a dataset portion comprising a first number of memory cells, the first number of memory cells comprising a first number of data bits stored thereon, the first number of data bits indicative of at least a portion of information stored on the memory array; and
a Column Redundancy (CR) portion comprising a second number of memory cells, the second number of memory cells configured to comprise:
a second number of data bits remapped from the dataset portion and stored on a portion of the second number of memory cells, the second number of data bits are less than the second number of memory cells; and
a third number of data bits indicative of at least a portion of additional information for identifying a likely defective memory cell stored at least on a portion of the remaining memory cells.

16. The apparatus of claim 15, wherein the memory device is configured to correct an erroneous data bit associated with the first dataset portion by accessing the first additional bits.

17. The apparatus of claim 16, wherein:
the memory device is configured to correct a first number of erroneous data bits of the first number of data bits using an ECC stored in association with the first dataset portion; and
the memory device is configured to correct an additional erroneous data bit of the first number of data bits using the first additional bits.

18. The apparatus of claim 15, the memory array comprises a second data segment, the second data segment comprising a second CR portion comprising a second number of CR memory cells, the second number of CR memory cells configured to store second additional bits, wherein the second additional bits comprise at least a second portion of the additional information associated with an address of a first memory cell associated with the memory device, wherein the memory device is configured to correct an erroneous data bit associated with the first dataset portion by accessing the first additional bits and the second additional bits.

19. The apparatus of claim 15, wherein the memory device comprises:
a second data segment comprising a second CR portion, the second CR portion is configured to store second additional bits;
a third data segment comprising a third CR portion, the third CR portion is configured to comprise third additional bits; and
a fourth data segment comprising a fourth CR portion, the fourth CR portion is configured to comprise fourth additional bits;
wherein the memory device is configured to use the first additional bits, second additional bits, third additional bits, and fourth additional bits to identify position of an erroneous data bit stored on the first dataset portion.

20. The apparatus of claim 19, wherein at least a portion of the additional information stored on the first additional bits, the second additional bits, the third additional bits, or the fourth additional bits is associated with a redundant ECC, wherein the memory device is configured to use the redundant ECC to identify at least an erroneous bit.
